(19) United States
(12) Patent Application Publication
(10) Pub. No.: US 2025/0179628 A1
(43) Pub. Date: Jun. 5, 2025

(54) ORGANIC VAPOR JET PRINTING SYSTEM

(71) Applicant: Universal Display Corporation, Ewing, NJ (US)

(72) Inventors: Gregory McGraw, Yardley, PA (US); George Fitzgerald, Lambertville, NJ (US)

(21) Appl. No.: 18/947,770

(22) Filed: Nov. 14, 2024

Related U.S. Application Data
(60) Provisional application No. 63/605,005, filed on Dec. 1, 2023.

(51) Int. Cl. C23C 16/18; C23C 16/455; C23C 16/46

(52) U.S. Cl. CPC C23C 16/18; C23C 16/45563; C23C 16/46

(57) ABSTRACT

A vapor deposition system comprising an array of depositors in fluid communication with an ambient inert gas that are held in proximity to substrate carried on a heated conveyance such that the substrate and depositors move relative to each other during deposition. Here, each depositor has one or more delivery apertures that ejects a gas jet including a vapor precursor that chemically reacts with the substrate surface to form a single-molecule thick layer of electroluminescent compound on the substrate. Further, each depositor has one or more exhaust apertures that cumulatively withdraw a greater molar flow of gas than is cumulatively ejected by the delivery apertures in the same depositor.

### CROSS-REFERENCE TO RELATED APPLICATIONS

This application claims priority to U.S. provisional application No. 63/605,005 filed on Dec. 1, 2023, incorporated herein by reference in its entirety.

### FIELD

The present invention relates to organic vapor jet printing (OVJP)-type devices and techniques for fabricating organic emissive devices, such as organic light emitting diodes, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, each of which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which comprises a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level of the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more devices selected from a consumer product, an electronic component module, and/or a lighting panel.

In one aspect a vapor deposition system comprises an array of depositors in fluid communication with an ambient inert gas that are held in proximity to substrate carried on a heated conveyance such that the substrate and depositors move relative to each other during deposition, wherein each depositor has one or more delivery apertures that ejects a gas jet including a vapor precursor that chemically reacts with the substrate surface to form a single-molecule thick layer of electroluminescent compound on the substrate, and wherein each depositor has one or more exhaust apertures that cumulatively withdraw a greater molar flow of gas than is cumulatively ejected by the delivery apertures in the same depositor.

In one embodiment, a temperature of the substrate surface exceeds a temperature of the depositor.

In one embodiment, the temperature of the substrate is between 100° C. and 200° C. In one embodiment, the temperature of the substrate is between 60° C. and 180° C.

In one embodiment, the pressure of the ambient inert gas is between 20 Torr and 300 Torr.

In one embodiment, the depositor array is held between 20 μm and 60 μm from the substrate.

In one embodiment, wherein the delivery or exhaust apertures have a minor width between 5 μm and 50 μm.

In one embodiment, each depositor has a width of between 40 μm and 400 μm.

In one embodiment, the vapor precursor comprises an organometallic compound capable of undergoing pyrolysis and chemically binding to the substrate.

In one embodiment, the vapor precursor a transition metal tris-acetylacetonate.

In one embodiment, the deposited material is affixed to the substrate via one or more of ether groups, thioether groups, and acetylthio groups.

In one embodiment, the deposited material forms a continuous monolayer on a region of substrate acted on by a depositor.

In another aspect, an organic vapor jet printing (OVJP) deposition device comprises one or more depositors, wherein at least one of the one or more depositors comprises one or more delivery apertures, one or more exhaust apertures, wherein at least one of the one or more exhaust apertures is fluidly coupled to at least one delivery aperture of the one or more delivery apertures, and a substrate, wherein the one or more delivery apertures are configured to eject a gas jet including a vapor precursor onto the substrate causing a chemical reaction between the vapor precursor and the substrate.

In one embodiment, the device further comprises a heated substrate chuck configured to hold and provide heat to the substrate.

In one embodiment, the device is configured to form a single-molecule thick layer of sorbate on the substrate via a chemical reaction between the vapor precursor and the substrate.

In one embodiment, the one or more exhaust apertures are configured to withdraw a molar flow of gas larger than a molar flow of the gas ejected by the one or more delivery apertures.

In one embodiment, a temperature of the substrate is higher than a temperature of the vapor precursor material.

In another aspect, a temperature of the substrate is between 100° C. and 200° C.

In one embodiment, a temperature of the substrate is between 60° C. and 180° C.

In one embodiment, a pressure of the ambient inert gas is between 20 Torr and 300 Torr.

In one embodiment, at least one of the one or more delivery apertures has a minor axis dimension between 5 μm and 50 μm.

In one embodiment, at least one of the one or more depositors has a width between 40 μm and 400 μm, wherein the width is perpendicular to the printing direction.

In one embodiment, one or more depositors are positioned 20 μm to 60 μm from the substrate.

In one embodiment, the vapor precursor comprises an organometallic compound.

In one embodiment, the vapor precursor is configured to chemically bond to the substrate via covalent bonds.

In one embodiment, the covalent bonds are formed via one or more of ether groups, thioether groups, and acetylthio groups.

In another aspect, a vapor deposition system comprises a substrate including a conductive oxide layer in thermal connection to a heater, and a nozzle block facing the conductive oxide layer, comprising at least one delivery aperture configured to eject an organic vapor, and at least one exhaust aperture proximate to the at least one delivery aperture, configured to create a deposition zone by intaking an ambient confining gas and at least a portion of the ejected organic vapor, wherein a total volumetric flow rate of the ejected organic vapor is less than the total volumetric flow rate that the at least one exhaust aperture intakes, wherein the heater is configured to heat the substrate to between 60° C. and 200° C., wherein the ambient confining gas has a pressure between 20 Torr and 300 Torr, and wherein the nozzle block is positioned between 20 μm and 60 μm from the substrate.

In one embodiment, the organic vapor is configured to condense on the substrate or conductive oxide to form an electroluminescent film.

In one embodiment, the electroluminescent film comprises a monolayer.

### BRIEF DESCRIPTION OF THE DRAWINGS

FIG. 1 shows an organic light emitting device.

FIG. 2 shows an inverted organic light emitting device that does not have a separate electron transport layer.

FIGS. 3A and 3B show an exemplary OVJP depositor.

FIG. 4 shows the emissive layer of an OLED deposited by the current embodiment of OVJP.

FIG. 5 shows a depiction of organic vapor reacting with a substrate surface to form a monolayer.

FIG. 6 shows a comparison of the thickness cross-section of a thin film printed by the current OVJP process with that of an organic monolayer deposited by the disclosed process.

FIG. 7 shows the thin film layer structure of an OLED fabricated using the disclosed process.

FIG. 8 shows the architecture of a full color OLED pixel comprised of side-by-side red, green, and blue subpixels fabricated using the disclosed process.

FIG. 9 shows a flowchart of the steps required to fabricate an OLED using the disclosed process.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

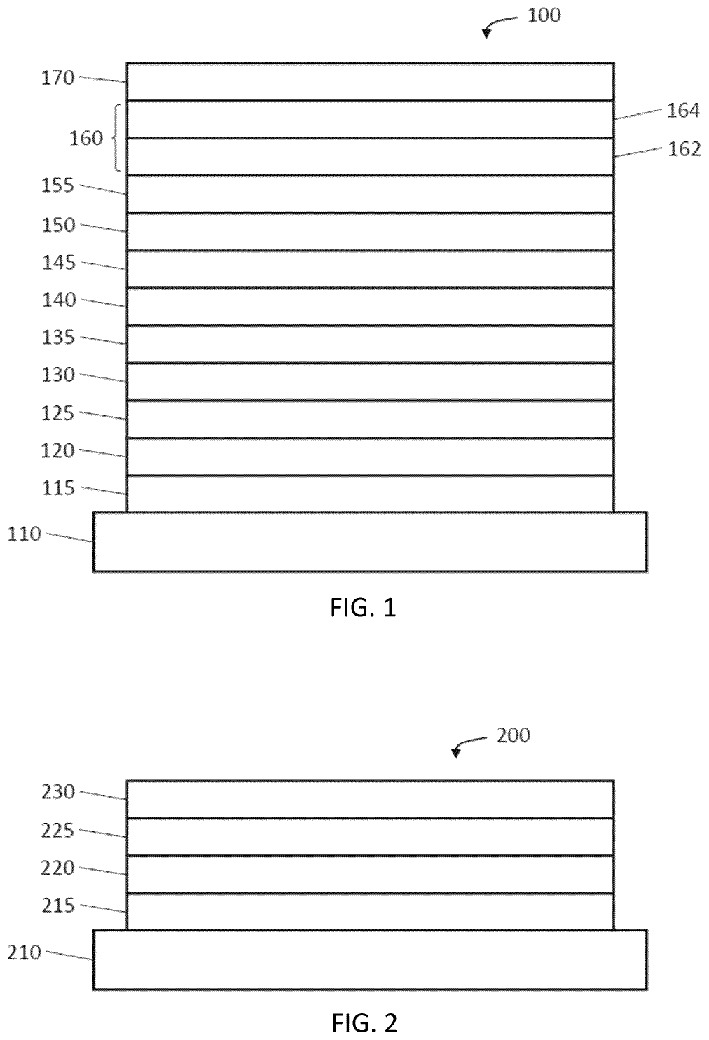

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that comprises quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material comprising quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably comprising at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material comprises essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL comprises the same molecule or the same functional groups used as one of the hosts described below.

### Host:

The light emitting layer of the organic EL device of the present invention preferably comprises at least a metal complex as light emitting material, and may comprise a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, deposition within a feature to be printed by OVJP is non-uniform. Therefore, the thickness cross-section of a printed line is uneven and is usually thicker at the center of the printed feature relative to the edges of the active width of the feature. Here, the active width is the width of the line that overlays an electrode and can be illuminated. The active width is itself limited by intra-line thickness uniformity. Additionally, variation in film thickness across the active width can create efficiency and lifetime issues in OVJP printed devices. Furthermore, variations in average thickness between printed lines or along the length of the printed lines may create mura in a display.

In contrast to other deposition techniques, such as organic vapor phase deposition (OVPD), chemical vapor deposition (CVD), atomic layer deposition (ALD), and the like which are designed to deposit blanket layers of material over a substrate, OVJP techniques deposit narrow lines of material, sometimes but not limited to organic material, on a substrate without the use of a shadow mask, fine metal mask, or equivalent device.

Conventional devices and techniques employed to produce displays such as mobile phone and laptop displays often use evaporation sources and fine metal masks to pattern the deposition, for example as are common with non-OVJP deposition techniques. Fine metal masks are typically not suitable for use in manufacturing large area displays because the masks cannot be stretched with sufficient force to prevent sagging. Inkjet printing is a potential patterning technique for Organic Light Emitting Diode (OLED) displays, but the use of solvents to make the inks seriously degrades the performance of the light emitting devices. OVJP eliminates these two issues by printing lines having pixel width without the use of fine metal masks. Notably, OVJP uses state-of-the-art OLED materials, or other materials, without dissolving them in a solvent.

In some embodiments, OVJP is being used to deposit lines of a precursor material that reacts with a substrate, or previously deposited materials on a substrate, to form a monolayer of material and more specifically an electroluminescent material. In an embodiment, monolayer formation is self-limiting so the entire printed width of the line will be one monolayer thick. In other words, the print head of the OVJP device may dwell over an area long enough for a monolayer to form over the entire area without surplus material being deposited over portions of that area. In an embodiment, the convective curtain generated by the OVJP depositors prevents precursor material from leaving the intended deposition zone, and this allows for precise patterning. In an embodiment, the materials may be deposited on a line of sub-pixels or pixels without contaminating neighboring subpixels or pixels. Alternatively, materials may be deposited in a specific area without depositing materials/contaminating any neighboring areas. For example, a side-by-side RGB display may be fabricated by depositing red, green, and blue electroluminescent monolayers over the electrodes of their respective pixels.

In an embodiment, disclosed herein is a method for maskless additive patterning of a monolayer of material, for example an electroluminescent material, on an electrode substrate to permit fabrication of a display, for example an RGB display. The method includes sequentially depositing precursors that react to form red, green, and blue emitting materials each on different electrodes using OVJP.

Embodiments of the present invention provide for identifying an appropriate material system (precursor materials and electrode material) and then printing arrays of devices on a properly prepared substrate using OVJP. In an embodiment, conventional vacuum thermal evaporation (VTE) may then be used to deposit an electron transport layer, electrode materials, or other layers known in the art. In an embodiment, maskless additive patterning of a monolayer of electroluminescent material on an electrode substrate permits an RGB display to be fabricated by sequentially depositing precursors that react to form red, green, and blue emitting materials on each different electrode using OVJP.

In an embodiment, the materials used may include M(B)k(C)l(D)m(E)n where the material is emissive; M is a transition metal; B, C, D, E are ligands coordinated to the metal; k+l+m+n represents the maximum number of ligands that can bond to the metal; and any of the ligands B, C, D, E are capable of forming covalent bonds to a metal or metal oxide surface. In an alternative embodiment, one or more of the ligands B, C, D, E is removed from the material and the metal M is capable forming covalent bonds to the surface.

In an embodiment, the vapor precursor could be a cyclopentadienyl metal complex such as (methylcyclopentadienyl) trimethylplatinum. In alternative embodiments, the vapor precursor may include, but is not limited to, (Trimethyl)methylcyclopentadienylplatinum (IV), Bis(ethylcyclopentadienyl)magnesium, Cyclopentadienylindium (I), Bis(cyclopentadienyl)ruthenium (Ruthenocene), Bis(ethylcyclopentadienyl)ruthenium (II), Bis(ethylcyclopentadienyl)manganese, Cyclopentadienylcobalt dicarbonyl,

Tris(methylcyclopentadienyl)yttrium, (Methylcyclopentadienyl)(1,5-cyclooctadiene) iridium (I), and/or transition metal tris-acetylacetonates. In the transition metal tris-acetylacetonates the metals include, but are not limited to Al, Sc, Cr, Mn, Fe, Co, Ru, Rh, In, Ir, Pt, Pd. Alternatively, the metals include, but are not limited to, barium, bismuth, cerium, chromium, cobalt, copper, dysprosium, erbium, gadolinium, hafnium, indium, iron, lanthanum, magnesium, manganese, molybdenum, neodymium, nickel, niobium, osmium, platinum, praseodymium, rhenium, rhodium, ruthenium, samarium, thallium, thulium, titanium, tungsten, vanadium, ytterbium, yttrium, and zirconium. In an alternative embodiment, the metals may include iridium-based, platinum-based, rhodium-based, or palladium-based metal halides, metal β-diketonates, carbonyl complexes, allyl complexes, cyclopentadienyl complexes, cyclooctadienyl complexes, alkyl complexes, metal carboxylate, metal phosphines, and/or ethylene complexes. In yet another alternative embodiment, the vapor precursor may be any metal chelated to ligands where the ligands can be removed by heat, oxidation (e.g., by O₂, H₂O), or reduction (e.g., by H₂, NH₃) in the gas phase.

In an embodiment, the vapor deposition system may deposit material affixed to the substrate by either or thioether groups or acetylthio groups that are attached to ligands B, C, D, or E. In an embodiment, the vapor deposition system may deposit any dopant material, like a volatilizable compound like (1-((4-acetylthiophenyl)ethynyl)-4-((4-pyridyl)ethynyl)benzene) or such a compound with an active organometallic group attached.

As previously disclosed, one type of technique for fabricating OLEDs and similar devices is OVJP, a maskless, solventless approach to printing large area OLED displays. In OVJP, narrow lines of OLED material are printed on the display backplane using a series of apertures formed in a silicon die, which may be manufactured using Microelectromechanical systems (MEMS) technology. Specific examples of OVJP systems are disclosed in U.S. Pat. Nos. 10,170,701 and 11,267,012, the disclosures of each of which are incorporated herein by reference in its entirety, and U.S. application Ser. Nos. 16/245,554 and 16/324,703, the disclosures of each of which are incorporated herein by reference in its entirety.

When OVJP systems and techniques are used to fabricate OLEDs and similar devices, OLED material is printed over columns of anodes which are separated by thin lines of insulating material. To maximize display performance the ratio of anode area to pixel separation area is maximized. This requires the OVJP print profile to approximate a square wave profile; the profile must have steep sidewalls and a flat top between the sidewalls. Computational flow dynamics (CFD) modeling of the deposition profile often is used to aid in the design of the apertures. CFD-modeled aperture designs can produce deposition profiles with steep sidewalls or flat tops. However, as described in further detail herein, it has been found that when such designs are combined in a single mirror symmetric die, the actual deposition profile may deviate considerably from the predicted profile. CFD loses predictive power when evaluating depositors with very small features. Print die geometries disclosed herein permit the printing of profiles having steep sidewalls and a flat top using print apertures of moderate size. Additionally, depositor arrangements disclosed herein provide fully decoupled depositors as well as combinations of such decoupled depositors in a fully functional printing array.

In contrast to other deposition techniques, such as organic vapor phase deposition (OVPD), chemical vapor deposition (CVD), atomic layer deposition (ALD), and the like which are designed to deposit blanket layers of material over a substrate, OVJP techniques deposit narrow lines of organic material on a substrate without the use of a shadow mask, fine metal mask, or equivalent device.

Conventional devices and techniques employed to produce displays such as mobile phone and laptop displays often use evaporation sources and fine metal masks to pattern the deposition, for example as are common with non-OVJP deposition techniques. Fine metal masks are typically not suitable for use in manufacturing large area displays because the masks cannot be stretched with sufficient force to prevent sagging. Inkjet printing is a potential patterning technique for Organic Light Emitting Diode (OLED) displays, but the use of solvents to make the inks seriously degrades the performance of the light emitting devices. OVJP eliminates these two issues by printing lines having pixel width without the use of fine metal masks. Notably, OVJP uses state-of-the-art OLED materials without dissolving them in a solvent.

In OVJP, OLED materials are heated in an enclosed container to an elevated sublimation temperature and transported to a printhead through heated gas lines using an inert carrier gas. The printhead comprises jetting apertures with a spacing that corresponds to the pixel pitch of the display. Apertures are formed in silicon wafers using standard micro-electromechanical systems (MEMS) fabrication techniques. Functional OVJP dies are cut from the wafer, with the apertures located along one face of the die. Excess organic material is removed from the printing area by vacuum channels inserted into the print die. The aperture face of the die is held above a moving display backplane, and lines corresponding to the pixels are printed on the backplane.

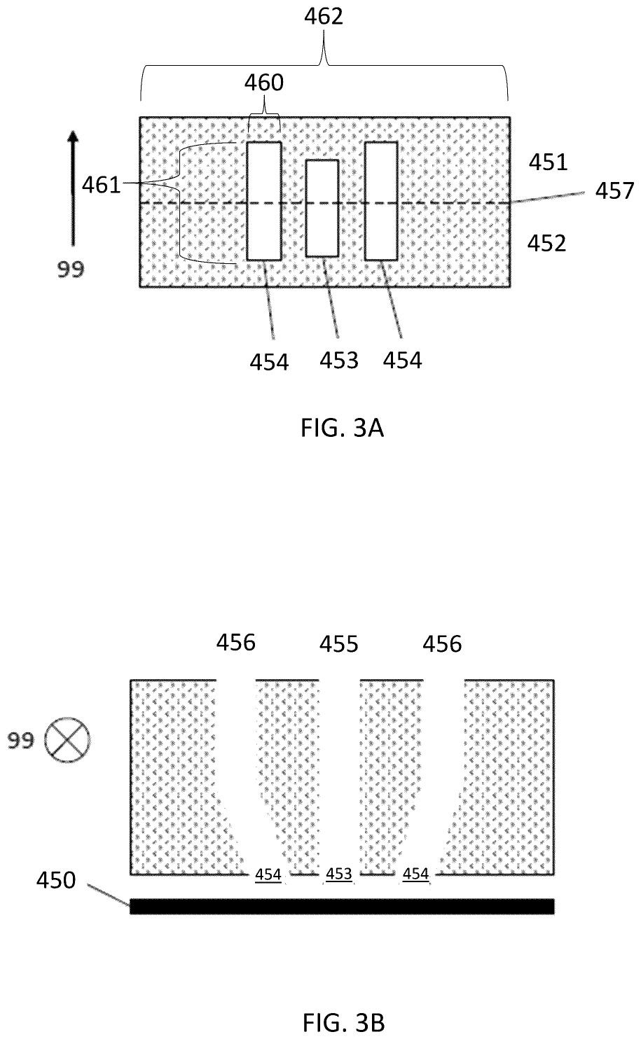

An example of an OVJP depositor with a single delivery aperture is shown in FIGS. 3A-3B. FIG. 3A shows the depositor face-on as it would appear from the substrate surface, which may be positioned above or below the depositor, with a surface of the substrate on which material is to be deposited arranged toward the depositor. The delivery aperture 453 is flanked by two exhaust apertures 454. The die is fabricated from two Si wafers 451 and 452, with shaded/stippled areas indicating regions of solid wafer material and unshaded areas indicating apertures on the edge of the die. The midline of the depositor 457 corresponds to the joint formed between the two halves of the die by wafer bonding as previously disclosed. The apertures are formed by etching channels into the faces of two wafers 451, 452 and bonding the two wafers together. The direction of relative motion of the depositor in relation to a substrate on which material is to be deposited is shown by the arrow 99, which is used throughout the drawings to indicate the same. The apertures (453, 454) may have any suitable geometry, including but not limited to, square, rectangular, triangular, circular, round, ovular, and n-gonal where n is greater than 2.

FIG. 3B shows a cross-sectional view of the channels within a die and normal to the scan direction of printing, arranged above the substrate 450. The delivery and exhaust apertures 453, 454, respectively in FIG. 3A are formed by terminating delivery 455 and exhaust 456 channels etched into each wafer at the lower edge of the die to form an aperture array.

The various depositors disclosed herein may be fabricated by etching the described channels and apertures in one or more wafers, then bonding the wafers to one another to achieve the described arrangement of apertures. As part of the bonding process, the matching delivery and/or exhaust apertures and channels in each wafer may be aligned or offset to achieve the desired arrangement of apertures

Further exemplary OVJP systems, methods, and details are described in U.S. patent application Ser. Nos. 18/104,353, 18/311,550, and 18/228,892, the disclosures of each of which are incorporated herein by reference in its entirety.

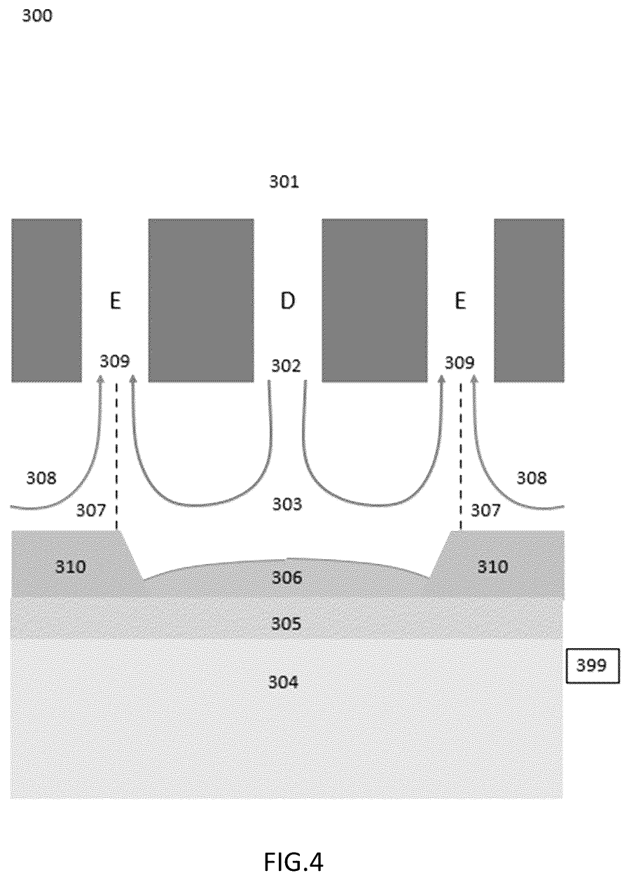

FIG. 4 shows a cross section of a subpixel in an OLED display being printed by an embodiment of an OVJP depositor. A nozzle block 301 including a delivery aperture 302 ejects a jet 303 of organic vapor entrained in an inert carrier gas onto a substrate 304. A thin film of transparent conductive oxide 305 on the substrate surface acts as the anode of the completed OLED in this example. The organic vapor in the jet condenses on the substrate in a region underneath the delivery aperture to form a thin film 306 of electroluminescent material. The width of the deposition zone is bounded by two stagnation planes 307 defined by the location where the outward motion of the jet is blocked by an inward flowing current of confinement gas 308 drawn from the environment surrounding the depositor. The flow of confinement gas prevents organic vapor from spreading beyond the stagnation plane. This permits high resolution printing by preventing organic material intended for one subpixel from spreading into and/or contaminating neighboring subpixels. Confinement gas, inert gas from the jet, and surplus organic vapor are all drawn into exhaust apertures 309 disposed next to the delivery apertures on the nozzle block. The exhaust apertures cumulatively withdraw a greater molar flow of gas from the printing zone than the deliver apertures eject, assuring an inward flow of confinement gas. The illuminated width of the pixel is defined by a non-conductive pixel defining layer (PDL) 310 that is defined on the substrate prior to OVJP deposition. The PDL ensures the illuminated regions of the thin film stack are uniform and high quality. The edges of both the printed thin film and the electrode may otherwise be detrimental to device performance.

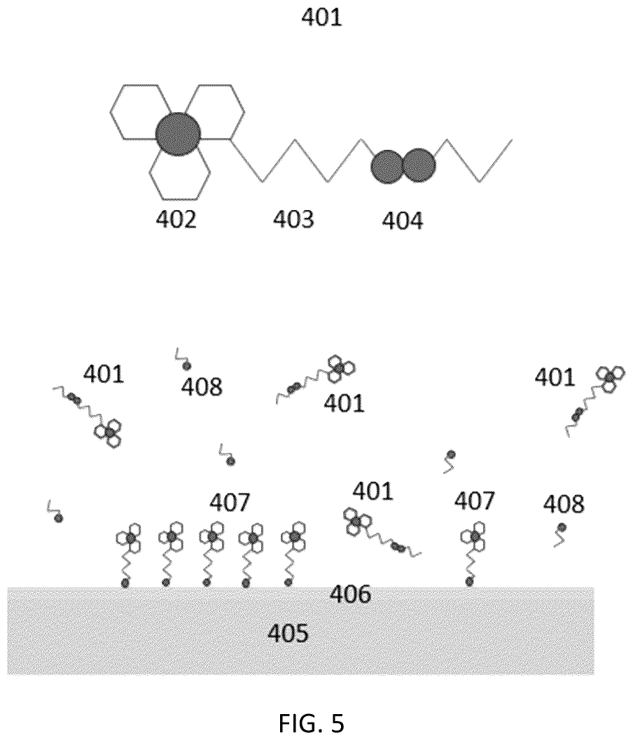

FIG. 5 shows a stylized depiction of the Metalorganic Chemical Vapor Deposition (MOCVD) reaction. The precursor molecules 401 used for this reaction may vary, but a typical precursor may comprise an organometallic group 402 that acts as a site for radiative exciton recombination and a tether group 403 that links the organometallic group to reactive group 404. A tether group of finite length is shown here, but the disclosed technique may also be used with precursor species that have a reactive group directly attached to an organometallic group, making the tether group zero length. The reactive group may include a relatively weak chemical bond such as an ether or thioether that breaks on contact with the substrate surface and chemisorbs the organometallic group to the substrate. Precursor molecules are transported to the substrate 405 in vapor phase. The precursor molecules may react with an activated metal or metal oxide film 406 on the substrate to form a molecular monolayer of electroluminescent material 407 that is chemically bonded to the substrate. The electroluminescent molecules in this layer may comprise the organometallic and tether groups from the precursor. An effluent group 408 may break away from the precursor molecule during chemisorption and remain in vapor phase. These are exhausted as a reaction byproduct. Given adequate precursor, the reaction will proceed until a monolayer of electroluminescent material is deposited on the substrate. No more material may be deposited once a monolayer is formed, since there are no sites available on the substrate for precursor to chemisorb.

In some embodiments, a vapor deposition system 300 comprises an array of depositors 301 in fluid communication with an ambient inert gas 308 that are held in proximity to substrate 304 carried on a heated conveyance 399 such that the substrate 304 and depositors 301 move relative to each other during deposition. In some embodiments each depositor 301 has one or more delivery apertures 302 that ejects a gas jet 303 including a vapor precursor that chemically reacts with the substrate surface to form a single-molecule thick layer of electroluminescent compound 306 on the substrate 304. In some embodiments, each depositor 301 has one or more exhaust apertures 309 that cumulatively withdraw a greater molar flow of gas than is cumulatively ejected by the delivery apertures 302 in the same depositor 301.

In one embodiment, a temperature of the substrate 304 surface exceeds a temperature of the depositor 301. In one embodiment, the temperature of the substrate is between 100° C. and 200° C., between 60° C. and 180° C., or between 40° C. and 350° C. In one embodiment, the pressure of the ambient inert gas is between 20 Torr and 300 Torr, between 10 Torr and 350 Torr, or between 100 Torr and 200 Torr.

In one embodiment, the depositor array 301 is held between 20 μm and 60 μm, between 10 μm and 100 μm, or between 30 μm and 50 μm from the substrate 304. In one embodiment, wherein the delivery and/or exhaust apertures have a minor width 460 between 5 μm and 50 μm and a major width 461 between 5 μm and 1000 μm. In one embodiment, each depositor 301 has a width 462 of between 100 μm and 1000μ m.

In one embodiment, the vapor precursor comprises an organometallic compound capable of undergoing pyrolysis and chemically binding to the substrate. In one embodiment, the vapor precursor a transition metal tris-acetylacetonate. In one embodiment, the deposited material is affixed to the substrate 304 via one or more of ether groups, thioether groups, and acetylthio groups. In one embodiment, the deposited material forms a continuous monolayer on a region of substrate 304 acted on by a depositor 301.

In some embodiments, an organic vapor jet printing (OVJP) deposition device 300 comprises one or more depositors 301, wherein at least one of the one or more depositors 301 comprises one or more delivery apertures 302, one or more exhaust apertures 309, wherein at least one of the one or more exhaust apertures 309 is fluidly coupled to at least one delivery aperture 302 of the one or more delivery apertures 302, and a substrate 304. In some embodiments, the one or more delivery apertures 302 are configured to eject a gas jet 303 including a vapor precursor onto the substrate 304 causing a chemical reaction between the vapor precursor and the substrate 304.

In one embodiment, the device further comprises a heated substrate chuck 399 configured to hold and provide heat to the substrate 304. In one embodiment, the device 300 is configured to form a single-molecule thick layer of sorbate on the substrate 304 via a chemical reaction between the vapor precursor and the substrate 304.

In one embodiment, the one or more exhaust apertures are configured to withdraw a molar flow of gas larger than a molar flow of the gas ejected by the one or more delivery apertures.

In one embodiment, a temperature of the substrate 304 is higher than a temperature of the vapor precursor material. In one embodiment, a temperature of the substrate 304 is lower than or equal to a temperature of the vapor precursor material. In another aspect, a temperature of the substrate 304 is between 100° C. and 200° C. In one embodiment, a temperature of the substrate 304 is between 60° C. and 180° C.

In one embodiment, a pressure of the ambient inert gas 308 is between 20 Torr and 300 Torr. In one embodiment, at least one of the one or more delivery apertures 302 has a minor axis dimension between 5 μm and 50 μm. In one embodiment, at least one of the one or more depositors 301 has a width between 40 μm and 400 μm, wherein the width is perpendicular to the printing direction. In one embodiment, one or more depositors 301 are positioned 20 μm to 60 μm from the substrate 304.

In one embodiment, the vapor precursor comprises an organometallic compound. In one embodiment, the vapor precursor is configured to chemically bond to the substrate via covalent bonds. In one embodiment, the covalent bonds are formed via one or more of ether groups, thioether groups, and acetylthio groups.

In some embodiments, a vapor deposition system 301 comprises a substrate 304 including a conductive oxide layer 305 in thermal connection to a heater 399, and a nozzle block 301 facing the conductive oxide layer 305. In some embodiments, the nozzle block 301 comprises at least one delivery aperture 302 configured to eject an organic vapor 303, and at least one exhaust aperture 309 proximate to the at least one delivery aperture 302, configured to create a deposition zone bounded by stagnation planes 307 by intaking an ambient confining gas 308 and at least a portion of the ejected organic vapor 303. In some embodiments, a total volumetric flow rate of the ejected organic vapor 303 is less than the total volumetric flow rate of the ambient confining gas 308 and the portion of ejected organic vapor 303 that the at least one exhaust aperture 309 intakes. In some embodiments, the heater 399 is configured to heat the substrate to between 60° C. and 200° C. In some embodiments, the ambient confining gas 308 has a pressure between 20 Torr and 300 Torr. In some embodiments, the nozzle block 301 is positioned between 20 μm and 60 μm from the substrate 304.

In one embodiment, the organic vapor 303 is configured to condense on the substrate 304 and/or conductive oxide 305 to form an electroluminescent film. In one embodiment, the electroluminescent film comprises a monolayer.

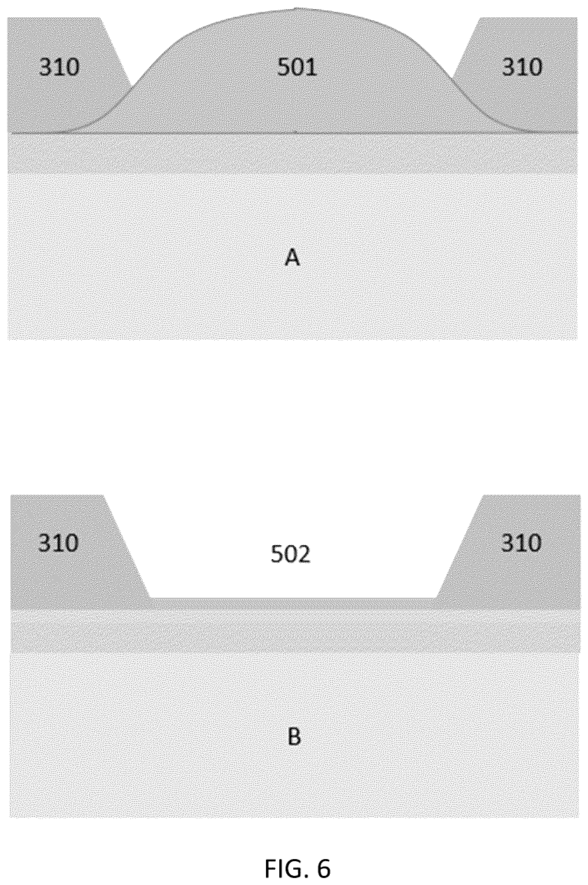

FIG. 6 shows a comparison of the print profiles generated by OVJP when depositing material by physical vapor deposition (PVD) with the profile expected when depositing an MOCVD precursor. The top figure shows the result of a PVD process by OVJP. The printed profile 501 is superimposed over the PDL for illustration purposes. (Note thickness are not to scale.) Deposition of organic vapor is more rapid near the center of the printing zone than the edges. This results in an uneven thickness profile for the printed film that may adversely affect device performance. Conversely, as shown in the bottom figure, a chemisorbed film of MOCVD precursor 502 is expected to form a uniform monolayer across the printing zone. In some embodiments, the deposition reaction is self-limiting, so material cannot build up in regions of higher flux. Furthermore, in some embodiments, the precursor cannot deposit on the PDL since it will not react. Here, non-reacting precursor is removed by the exhaust.

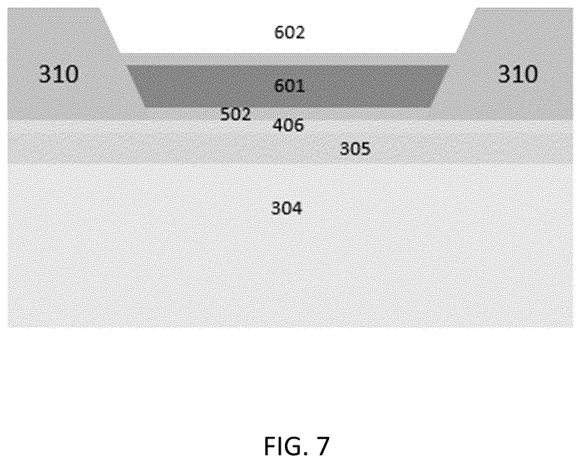

FIG. 7 shows an embodiment of an OLED produced by the disclosed process. The substrate 304 includes a transparent conducting oxide first electrode 305 and a pixel defining layer 310. The first electrode 305 may be an anode or a cathode as suitable. The first electrode 305 may be coated with an activated metal or metal oxide film 406 to which the precursor adsorbs. A monolayer of electroluminescent material 502 is formed when the precursor vapor reacts with the first electrode. A layer of electron transport material 601 may be deposited over the monolayer of electroluminescent material. Finally, a second electrode 602 may be deposited over the electron transport material. The second electrode 602 may be a cathode or an anode as suitable.

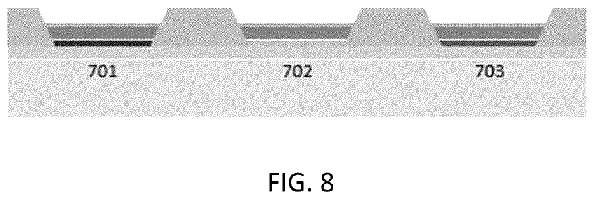

FIG. 8 shows a cross-section of an RGB pixel printed with this technique. Each subpixel has the structure illustrated in FIG. 7. The subpixels are differentiated only by receiving a red 701, green 702, or blue 703 monolayer of electroluminescent material. Each monolayer may be deposited on the substrate in successive steps using OVJP.

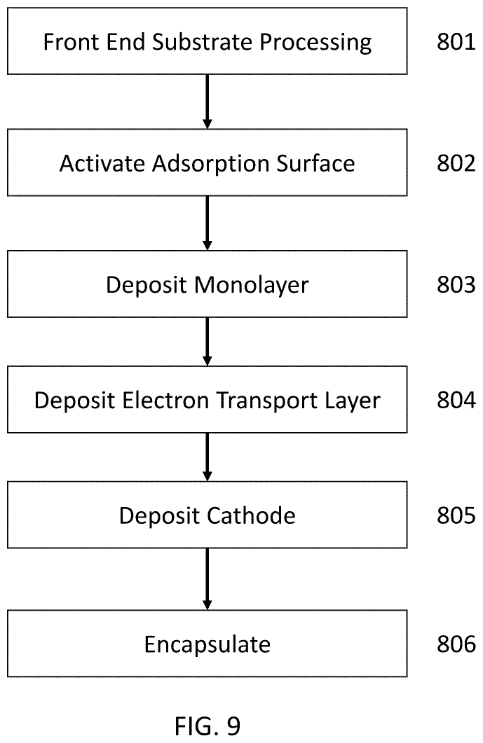

FIG. 9 shows a flowchart of a process that that may be used to fabricate OLEDs by the disclosed technique. Front end substrate processing 801 refers to the substrate preparation normally required prior to the deposition of organic material. This usually includes fabricating a backplane that may include active circuit elements, electrodes, and PDL layers. Substrate preparation may include depositing a thin layer of metal oxide may be deposited on the electrodes using an MOCVD precursor such as Ni(tta)2(tmeda) along with O2 and Ar. This deposition process typically occurs at a pressure of 1-10 Torr and a substrate temperature of 400 C.°

In an embodiment, adsorption surfaces on the electrodes must be activated 802 before a monolayer of organic electroluminescent material can be deposited. This must be done in an inert environment immediately prior to monolayer deposition. H₂O vapor and O₂ at a pressure of 300 Torr and 300° C. may be used to activate a metal oxide layer on the electrodes. A variety of other chemical treatments may be used to activate the electrode surface. Physical methods like plasma etching, ion milling, or laser ablation may also be used to create an active surface.

Next the monolayer of electroluminescent material 803 is deposited as disclosed herein using OVJP. Vapor phase precursors react with the metal or metal oxide surface to form a monolayer of emissive molecules. The vapor is entrained in an inert carrier gas such as N₂ or Ar at a gas pressure of between 10 and 200 Torr. Sources are heated to a temperature sufficient to evaporate the precursor, up to 400° C. The substrate is heated to between 10° and 300° C. A chemical bond between the precursor molecule and the activated substrate is formed as shown in the illustration below. Monolayers of material emitting different colors may be deposited on the different subpixels of an RGB array in successive deposition steps, with a different color of subpixel being coated in each step.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A vapor deposition system comprising:
an array of depositors in fluid communication with an ambient inert gas that are held in proximity to a substrate carried on a heated conveyance such that the substrate and depositors move relative to each other during deposition;
wherein each depositor has one or more delivery apertures that are configured to eject a gas jet including a vapor precursor that chemically reacts with the substrate surface to form a single-molecule thick layer of electroluminescent compound on the substrate; and
wherein each depositor has one or more exhaust apertures configured to cumulatively withdraw a greater molar flow of gas than is cumulatively ejected by the delivery apertures in the same depositor.

2. The vapor deposition system of claim 1, wherein a temperature of the substrate surface exceeds a temperature of the depositor.

3. The vapor deposition system of claim 2, wherein the temperature of the substrate surface is between 100° C. and 200° C.

4. The vapor deposition system of claim 2, wherein the temperature of the substrate surface is between 60° C. and 180° C.

5. The vapor deposition system of claim 1, wherein the pressure of the ambient inert gas is between 20 Torr and 300 Torr.

6. The vapor deposition system of claim 1, wherein the depositor array is held between 20 μm and 60 μm from the substrate.

7. The vapor deposition system of claim 1, wherein the delivery or exhaust apertures have a minor width between 5 μm and 50 μm.

8. The vapor deposition system of claim 1, wherein each depositor has a width of between 100 μm and 1000 μm.

9. The vapor deposition system of claim 1, wherein the vapor precursor comprises an organometallic compound capable of undergoing pyrolysis and chemically binding to the substrate.

10. The vapor deposition system of claim 1, wherein the deposited material is affixed to the substrate via one or more of ether groups, thioether groups, and acetylthio groups.

11. The vapor deposition system of claim 1, wherein the deposited material forms a continuous monolayer on a region of substrate acted on by a depositor.

12. An organic vapor jet printing (OVJP) deposition device comprising:
one or more depositors, wherein at least one of the one or more depositors comprises:
one or more delivery apertures;
one or more exhaust apertures, wherein at least one of the one or more exhaust apertures is fluidly coupled to at least one delivery aperture of the one or more delivery apertures; and
a substrate, wherein the one or more delivery apertures are configured to eject a gas jet including a vapor precursor onto the substrate causing a chemical reaction between the vapor precursor and the substrate.

13. The OVJP deposition device of claim 12, further comprising a heated substrate chuck configured to hold and provide heat to the substrate.

14. The OVJP deposition device of claim 12, wherein the device is configured to form a single-molecule thick layer of sorbate on the substrate via a chemical reaction between the vapor precursor and the substrate.

15. The OVJP deposition device of claim 12, wherein the one or more exhaust apertures are configured to withdraw a molar flow of gas larger than a molar flow of the gas ejected by the one or more delivery apertures.

16. The OVJP deposition device of claim 12, wherein a temperature of the substrate is higher than a temperature of the vapor precursor material.

17. The OVJP deposition device of claim 12, wherein a temperature of the substrate is between 100° C. and 200° C.

18-25. (canceled)

26. A vapor deposition system comprising:
a substrate including a conductive oxide layer in thermal connection to a heater; and
a nozzle block facing the conductive oxide layer, comprising:
at least one delivery aperture configured to eject an organic vapor; and
at least one exhaust aperture proximate to the at least one delivery aperture, configured to create a deposition zone by intaking an ambient confining gas and at least a portion of the ejected organic vapor;
wherein a total volumetric flow rate of the ejected organic vapor is less than the total volumetric flow rate that the at least one exhaust aperture intakes;
wherein the heater is configured to heat the substrate to between 60° C. and 200° C.;
wherein the ambient confining gas has a pressure between 20 Torr and 300 Torr; and
wherein the nozzle block is positioned between 20 μm and 60 μm from the substrate.

27. The system of claim 26, wherein the organic vapor is configured to condense on the substrate or conductive oxide to form an electroluminescent film.

28. The system of claim 27, wherein the electroluminescent film comprises a monolayer.
